(19) United States
(12) Patent Application Publication
(10) Pub. No.: US 2019/0345596 A1
(43) Pub. Date: Nov. 14, 2019

(54) VAPOR DEPOSITION MASK, VAPOR DEPOSITION DEVICE, METHOD OF MANUFACTURING VAPOR DEPOSITION MASK, AND METHOD OF MANUFACTURING ELECTROLUMINESCENCE DISPLAY DEVICE

(71) Applicant: Sharp Kabushiki Kaisha, Sakai City, Osaka (JP)

(72) Inventors: Yoshiharu KATAOKA, Sakai City (JP); Koji YAMABUCHI, Sakai City (JP)

(21) Appl. No.: 15/777,748

(22) PCT Filed: Dec. 2, 2016
(86) PCT No.: PCT/JP2016/085943

§ 371 Date: May 21, 2018

(51) Int. Cl. C23C 14/04; H05B 33/10

(52) U.S. Cl. CPC C23C 14/042; H05B 33/10

(57) ABSTRACT

A vapor deposition mask includes a mask substrate including a mask aperture, and a base material of the mask substrate includes fibrous micro cellulose.

### TECHNICAL FIELD

The disclosure relates to a vapor deposition mask, a vapor deposition device, a method of manufacturing a vapor deposition mask, and a method of manufacturing an electroluminescence display device.

### BACKGROUND ART

In recent years, flat panel displays have been utilized in various products and fields, and there are demands for flat panel displays having even larger sizes, even higher picture quality, and even lower power consumption.

In view of such circumstances, electroluminescence (referred to as EL below) display devices provided with organic EL elements utilizing the Electro Luminescence of organic or inorganic materials are attracting much attention as flat panel displays due to their excellent qualities, such as low voltage driving, high responsiveness, and self-luminosity, while being in a completely solid state.

In order to enable full color display, EL display devices include light emitting layers that emit light of the desired color corresponding to a plurality of sub pixels for constituting a pixel.

For example, the vacuum vapor deposition technique using a vapor deposition mask, referred to as a shadow mask, is used for patterning and forming the light emitting layers.

In order to enable a high-definition EL display device, vapor deposition of vapor deposition particles is carried out with high accuracy on a film formation target substrate, so it is necessary to form high accuracy openings in the vapor deposition mask.

The vapor deposition mask in the related art is typically produced by processing a mask substrate made from a metal plate, using a metal mask having openings in a given pattern. A vapor deposition mask is normally used fixed to a mask frame.

However, with the existing metal processing technology, it may be difficult to form the openings in the metal plate with accuracy. Also, when the metal mask is used as the vapor deposition mask, it may be difficult to form a high definition vapor deposition film pattern due to the effect of positional offset, warping, and the like, resulting from thermal expansion of the metal plate.

In particular, in recent years, in the field of EL display devices, as in the field of liquid crystal display devices, an increase in the number of pixels per inch in the display device is demanded for even higher picture quality. However, in using a selectively patterning vapor deposition method with a metal mask, there is a limit to the processing accuracy of a metal mask, in other words, the positional accuracy of the openings themselves in the metal mask, and the opening pattern accuracy. Therefore, it may be difficult to form a high definition vapor deposition film suitable for 300 ppi or higher on a substrate.

Also, when a vapor deposition mask made from metal only is used as the vapor deposition mask, the mass increases as the vapor deposition mask becomes larger, and the total mass including supporting members such as the mask frame and the like increases, which may cause difficulties in handling.

Therefore, in recent years, vapor deposition masks using resin as the material of the vapor deposition mask have been proposed to reduce the weight and increase the accuracy of the openings.

For example, in PTL 1, a resin mask is disclosed as the vapor deposition mask, and such a resin mask includes a plurality of openings in a resin film in which a magnetic layer that includes magnetic particles over the whole surface is provided.

Resin can be used for forming high accuracy openings by laser processing, or the like, and thus the accuracy of the vapor deposition film pattern can be improved. Also, by using resin as the material of the vapor deposition mask, the vapor deposition mask can be made lighter.

### CITATION LIST

### Patent Literature

PTL 1: JP 2014-201819 A (published Oct. 27, 2014).

### SUMMARY

### Technical Problem

As in PTL 1, when the vapor deposition mask is formed from resin, the strength of the vapor deposition mask is reduced. Therefore, to maintain sufficient strength in the vapor deposition mask, the thickness of the vapor deposition mask can be increased.

Increasing the thickness of the vapor deposition mask causes so-called shadows to be produced at the portions where there is no vapor deposition and where the film thickness is smaller than the intended vapor deposition film thickness. Therefore, it may be difficult to form a high definition vapor deposition film pattern.

The disclosure has been made in view of the above issues and an object of the disclosure is to provide a vapor deposition mask that is light, thin, and high in strength and that enables formation of a high definition vapor deposition film pattern, a vapor deposition device, a method of manufacturing a vapor deposition mask, and a method of manufacturing an electroluminescence display device using such a vapor deposition mask.

### Solution to Problem

To address the above issue, a vapor deposition mask according to one aspect of the disclosure includes: a first mask substrate including a first aperture for causing a vapor deposition particle for forming a vapor deposition film on a film formation target substrate to pass. A base material of the first mask substrate includes micro cellulose in fiber form.

To address the above issue, a vapor deposition device according to one aspect of the disclosure includes: a vapor deposition mask according to one aspect of the disclosure; and a vapor deposition source configured to emit the vapor deposition particle towards the vapor deposition mask.

To address the above issue, a method of manufacturing a vapor deposition mask according to one aspect of the disclosure, the vapor deposition mask including a first mask substrate including a first aperture on the first mask substrate for causing a vapor deposition particle for forming a vapor deposition film on a film formation target substrate to pass, is a method including: forming the first mask substrate. In the forming, the first mask substrate including micro cellulose in a base material is formed by using a material including micro cellulose in fiber form.

To address the above issue, a method of manufacturing an electroluminescence display device according to one aspect of the disclosure is a method in which a vapor deposition film is formed on a film formation target substrate by using the vapor deposition mask according to one aspect of the disclosure. The vapor deposition film is a light emitting layer of the electroluminescence display device. The film formation target substrate is an electrode substrate of the electroluminescence display device. The light emitting layer is formed as a film on the electrode substrate.

### Advantageous Effects of Disclosure

According to one aspect of the disclosure, a vapor deposition mask that is light, thin, and has high strength and that enables a high definition vapor deposition film pattern to be formed, a vapor deposition device, a method of manufacturing a vapor deposition mask, and a method of manufacturing an electroluminescence display device using such a vapor deposition mask can be provided.

### BRIEF DESCRIPTION OF DRAWINGS

FIG. 1 is a plan view illustrating a partial enlargement of a schematic configuration of a vapor deposition mask according to a first embodiment of the disclosure.

FIG. 2 illustrates an example of the schematic configuration of a vapor deposition device that includes the vapor deposition mask according to the first embodiment of the disclosure.

FIG. 3A is an exploded perspective view illustrating an example of the schematic configuration of a vapor deposition mask that includes a mask frame, according to the first embodiment of the disclosure.

FIG. 3B is a cross-sectional view illustrating another example of the schematic configuration of the vapor deposition mask that includes a mask frame according to the first embodiment of the disclosure.

FIG. 4 is a plan view illustrating a relevant part of another vapor deposition mask according to the first embodiment of the disclosure, with micro-cellulose 2 aligned along one axis.

FIGS. 5A and 5B are cross-sectional views illustrating an example of a process for manufacturing the vapor deposition mask according to the first embodiment of the disclosure as a sequence of processes.

FIG. 6A is a cross-sectional view schematically illustrating the outline configuration of a vapor deposition substrate in one process for manufacturing a vapor deposition mask according to a second embodiment of the disclosure.

FIG. 6B is a cross-sectional view schematically illustrating an outline configuration of relevant parts of a mask substrate in a region R2 indicated on FIG. 6A.

FIG. 6C is a cross-sectional view schematically illustrating another example of an outline configuration of relevant parts of a mask substrate in the region R2 indicated on FIG. 6A.

FIG. 7A is a plan view illustrating an outline configuration of a relevant part of a vapor deposition mask according to a third embodiment of the disclosure.

FIG. 7B illustrates an example of the outline configuration of a vapor deposition device that includes the vapor deposition mask according to the third embodiment of the disclosure.

FIG. 8 illustrates an example of a schematic configuration of a vapor deposition device that includes a vapor deposition mask according to a fourth embodiment of the disclosure.

FIG. 9A is a plan view illustrating the outline configuration of relevant parts of a mask unit that includes a vapor deposition mask according to a fifth embodiment of the disclosure.

FIG. 9B is a plan view illustrating an outline configuration of the vapor deposition mask illustrated in FIG. 9A.

FIG. 9C is a cross-sectional view of the vapor deposition mask taken along line C-C in the direction of the arrows in FIG. 9B.

FIG. 9D is a cross-sectional view of the vapor deposition mask taken along line D-D in the direction of the arrows in FIG. 9B.

### DESCRIPTION OF EMBODIMENTS

A detailed description will be given of embodiments of the disclosure.

### First Embodiment

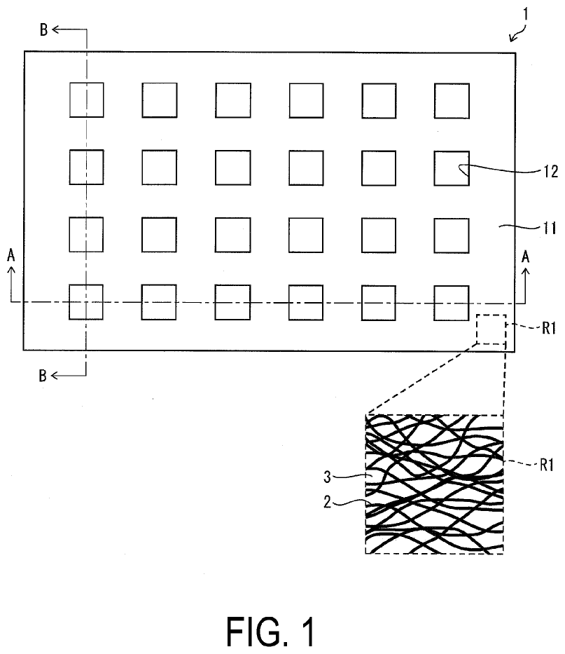

A description will be given of embodiments of the disclosure, on the basis of FIG. 1 to FIGS. 5A to 5B.

### Outline Configuration of Vapor Deposition Mask 1

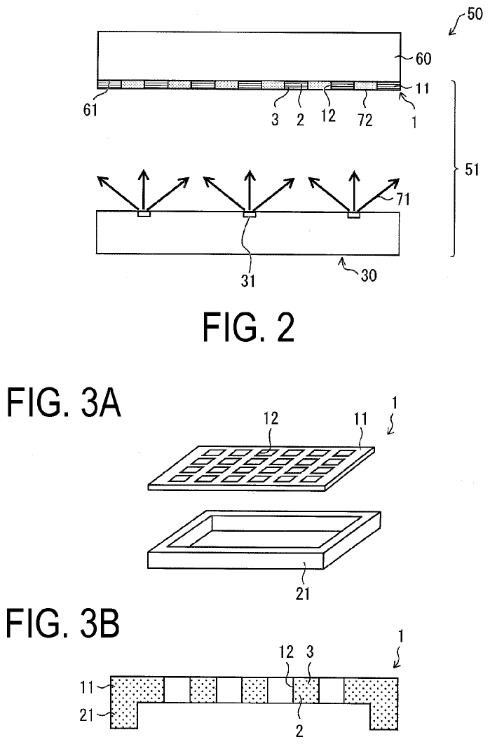

FIG. 1 is a plan view illustrating an enlargement of a part of the outline configuration of a vapor deposition mask 1 according to the present embodiment. Also, FIG. 2 illustrates an example of the outline configuration of a vapor deposition device 50 that includes the vapor deposition mask 1 according to the present embodiment. FIG. 3A is an exploded perspective view illustrating an example of the outline configuration of the vapor deposition mask 1 that includes a mask frame 21, according to the present embodiment. FIG. 3B is a cross-sectional view illustrating another example of the outline configuration of the vapor deposition mask 1 that includes the mask frame 21 according to the present embodiment. Note that the vapor deposition mask 1 illustrated in FIG. 2 schematically depicts a cross-section through the vapor deposition mask 1 corresponding to the cross section taken along line A-A in the direction of the arrows in FIG. 1. Also, the vapor deposition mask 1 illustrated in FIG. 3B schematically depicts a cross section through the vapor deposition mask 1 corresponding to the cross-section taken along line B-B in the direction of the arrows in FIG. 1.

As illustrated in FIG. 1, the vapor deposition mask 1 according to the present embodiment has a configuration in which through apertures that cause vapor deposition particles to pass are provided as mask apertures 12 (first apertures) on a main surface of a mask substrate 11 (substrate for masking, first mask substrate) having a thin plate-like shape and including, for example, micro cellulose 2 as a base material.

As illustrated in FIG. 2, the vapor deposition mask 1 is incorporated into the vapor deposition device 50, and serves as a mask for vapor deposition to be used for forming a vapor deposition film 72 with a predetermined pattern on a film formation target surface 61 of a film formation target substrate 60.

As illustrated in FIG. 2, the mask aperture 12 has a shape that is the same (substantially the same) as the pattern of the vapor deposition film 72 to be formed on the film formation target surface 61 of the film formation target substrate 60, or that corresponds to at least a portion of the pattern of the vapor deposition film 72.

Note that FIG. 1, as an example, illustrates a plurality of the mask apertures 12 each having a rectangular shape (a square shape illustrated in the example in FIG. 1) arranged in two dimensions (in matrix form) on the main surface of the vapor deposition mask 1.

However, the vapor deposition mask 1 is used for forming vapor deposition films 72 on film formation target substrates 60 using various kinds of materials such as inorganic materials, organic materials, electrode materials, dielectric materials, and insulating materials, from which EL layers (organic layers or inorganic layers) such as light emitting layers are configured in EL display devices such as organic EL display devices or inorganic EL display devices. Therefore, the shape and the arrangement of the mask apertures 12 are not limited to the above configuration.

The shape and the arrangement of the mask apertures 12 may be set as appropriate to obtain the desired vapor deposition film 72 pattern, in accordance with the type and application of the vapor deposition film 72, and in accordance with the vapor deposition method.

In other words, the shape of the mask apertures 12 can be changed not only in accordance with the application of the vapor deposition film 72 but also, for example, in accordance with whether scan vapor deposition is carried out by moving the vapor deposition mask 1 and the film formation target substrate 60 relative to each other and performing the vapor deposition, whether step vapor deposition is carried out by moving the position of the vapor deposition mask 1 relative to the film formation target substrate 60 to perform the vapor deposition and then positioning the vapor deposition mask 1 and the film formation target substrate 60 to perform the vapor deposition again, or whether fixed vapor deposition is carried out by performing vapor deposition with the vapor deposition mask 1 and the film formation target substrate 60 fixed in contact with each other.

Therefore, the shape and the arrangement of the mask apertures 12 is not limited to the above configuration, and, for example, may be in slot form or in slit form, and the like. Also, for example, the vapor deposition mask 1 may be an open mask with openings in a region corresponding to the whole image display region of the EL display device. Therefore, at least one mask aperture 12 may be provided. As stated above, in FIG. 1, an example in which a plurality of the mask apertures 12 is provided in a two-dimensional arrangement is illustrated, but the mask apertures 12 may be arranged in a one-dimensional direction only, or only one mask aperture 12 may be provided.

For example, the EL display device is manufactured by forming on a semiconductor substrate such as a TFT substrate or the like using a glass substrate or the like, an electrode substrate in which either a positive electrode or a negative electrode is formed, and forming on the electrode substrate a light emitting layer by vapor deposition of vapor deposition particles 71 including an organic material or an inorganic material using the vapor deposition mask 1, and forming on the vapor deposition film 72 obtained (in other words, the light emitting layer) the other electrode from among the positive electrode and the negative electrode.

In this case, the mask apertures 12 are provided to correspond to the sub pixels of the film formation target substrate 60, so that the vapor deposition particles 71 are not deposited in regions other than the target sub pixels of the film formation target substrate 60. In this way, only the vapor deposition particles 71 that have passed through the mask apertures 12 reach the film formation target substrate 60, and the vapor deposition film 72 is formed on the film formation target substrate 60 with a desired pattern in accordance with the shape of the mask apertures 12 corresponding to each of the sub pixels.

Note that the size of the vapor deposition mask 1 (size in plan view) may be set as appropriate in accordance with the vapor deposition method and the size of the film formation target substrate 60, and there is no particular limitation on the size. Also, the size (size in plan view) and the shape of the mask apertures 12 may be set as appropriate to obtain a desired vapor deposition film pattern, corresponding to the use of the vapor deposition film and the like, and there is no particular limitation on the size and shape. The conditions can be designed in the same way as, for example, a vapor deposition mask in the related art.

In FIG. 2, a case in which the vapor deposition mask 1 and the film formation target substrate 60 are fixed and in contact is illustrated as an example. When fixed vapor deposition is carried out with the vapor deposition mask 1 and the film formation target substrate 60 fixed and in contact with each other in this way, for example the vapor deposition mask 1 is formed to the same size as the film formation target substrate 60 in plan view, so that the whole film forming region of the film formation target substrate 60 is covered. Note that in the present embodiment, plan view indicates the view from the direction orthogonal to the main surface of the vapor deposition mask 1, in other words, the view from the direction normal to the vapor deposition mask 1 and the film formation target substrate 60.

However, the present embodiment is not limited to the above descriptions. For example, when scan vapor deposition is carried out by performing vapor deposition while scanning the film formation target substrate 60, the vapor deposition mask 1 and the film formation target substrate 60 are disposed separated from each other. In this case, the vapor deposition mask 1 is formed smaller than the film formation target substrate 60 (or more specifically, the length in the direction of relative movement between the vapor deposition mask 1 and the film formation target substrate 60 is shorter than the length of the film formation target substrate 60).

Also, the thickness of the vapor deposition mask 1 may be set as appropriate in accordance with the size (size in plan view), the mass, or the like of the vapor deposition mask 1. However, it may be desirable that the thickness of the vapor deposition mask 1, specifically the thickness of the mask substrate 11, be as thin as possible. By reducing the thickness of the mass substrate 11, the occurrence of shadows can be reduced.

In the present embodiment, the mask substrate 11 is formed from a material that includes micro cellulose 2. Therefore, sufficient strength can be maintained even when a thickness may be smaller than a thickness of a mask substrate in the related art, for example, may be 18 μm or less, and may be less than 10 μm.

Note that the thickness of the mask substrate 11 may be as small as possible, as stated above, but when the thickness of the mask substrate 11 is too small, bending may occur, and ease in handling may be reduced. Therefore, the thickness of the mass substrate 11 may be greater than 5 μm.

Note that the mask substrate 11 provided with the mask apertures 12 may be used as the vapor deposition mask 1 fixed in a support member such as the mask frame 21, which is formed separately from the mask substrate 11, as illustrated in FIG. 3A, or the mask substrate 11 and the mask frame 21 may be formed as the same member, as illustrated in FIG. 3B.

In the present embodiment, the micro cellulose 2 used as one of the materials of the mask substrate 11 is fiber cellulose having a width (thickness) of microns or smaller.

Natural cellulose fiber is formed from bundles of from several tens to several hundreds of cellulose molecules (cellulose chains), and is an assembly of cellulose microfibrils (also referred to as ultra fine fibers, or nano cellulose) with a fiber width from about 1 nm to about 100 nm. Each cellulose microfibril is strongly bonded with hydrogen bonds.

The micro cellulose 2 includes cellulose or its derivatives, having a fiber width in the order of microns or smaller, and is configured with cellulose microfibrils or cellulose microfibril assemblies.

As an example, the micro cellulose 2 can be obtained by, for example, size reduction of commercial cellulose such as α-cellulose or cellulose acetate or the like, so that the average fiber width (for example diameter) becomes a desired size of less than 1 μm, by using a finely dividing processing device, and carrying out defibrillation of pulp or the like down to such a desired size.

Note that there is no particular limitation on the method for defibrillation of commercial cellulose or pulp or the like down to the above size to manufacture the micro cellulose 2, and various commonly known methods can be used. For example, a homogenizer such as an ultrasonic homogenizer or the like, a mill such as a ball mill or a sand mail or the like, a high rotational speed mixer, or grinder, or the like that carries out defibrillation by mechanical processing can be used as the finely dividing processing device. In particular, defibrillation can be easily carried out by simple mechanical processing in an aqueous medium of cellulose that has been oxidized (TEMPO oxidation process) using an N-oxyl compound such as 2,2,6,6-tetramethylpiperidine 1-oxyl (TEMPO) or the like as an oxidizing catalyst.

There is no particular limitation on the raw material of the micro cellulose 2 provided the raw material includes cellulose, and various commonly known cellulose raw materials, for example, various types of pulp, bacterial cellulose, or the like can be used. Also, various types of commercial cellulose powder or fine crystalline cellulose powder or the like may be used.

Also, commercial micro cellulose may be used as the micro cellulose 2.

For example, cellulose microfibrils with a fiber width from about 1 nm to about 100 nm referred to as nano cellulose as described above can be used as the micro cellulose 2. Of the above-described several types of nano cellulose, so-called cellulose nanofibers having a fiber length that is relatively longer than the fiber width may be used.

Cellulose nanofibers are cellulose fibers that have been defibrillated down to a fiber width in the order of nanometers, that have high crystallinity, and that have excellent strength and heat resistance.

Cellulose nanofibers are fibrous cellulose having, for example, an average fiber width from about several nanometers to several tens of nanometers, and a fiber length from about 0.05 μm to several μm, in which from several to several tens of cellulose molecules are bonded in a crystalline state.

Note that there is no particular limitation on the fiber length of the micro cellulose 2 used in the present embodiment, provided a desired thickness of the vapor deposition mask 1 can be obtained.

The micro cellulose 2 has fine fibers, and the fibers are bonded together with several bonds, it is from ⅕ to 1/7 times the weight of steel, and has from five times to 10 times the strength (for example, the tensile rupture strength) of steel.

Also, in contrast to carbon fibers that have a density of 1.8 g/cm² and glass fibers that have a density of 2.5 g/cm², the density of the micro cellulose 2 (for example, the density of cellulose nanofibers) is low at 1.6 g/cm², so the mass per unit area is lower compared with carbon fibers and glass fibers. Therefore, by using the micro cellulose 2, the vapor deposition mask 1 can be made lighter than the case in which carbon fiber or glass fiber is used instead of the micro cellulose 2.

Moreover, the heat resistance of the micro cellulose 2 is higher than that of, for example, glass fiber, and the deformation (shrinkage) due to heat is extremely small being about ⅕ that of glass fiber, for example.

Therefore, by forming the vapor deposition mask 1 with a material that includes the micro cellulose 2, the vapor deposition masks 1 suitable for production of large-size film formation target substrates 60 can be obtained.

Also, unlike carbon fiber and glass fiber, micro cellulose 2 is a biomass resource capable of being produced and regenerated by photosynthesis of plants, so there is no concern over depletion, and mass production at low cost is possible in the future.

Also, for example, the diameter of cellulose nanofibers is small in the order of nanometers, and the nanofibers are transparent, so a transparent vapor deposition mask 1 is made available, although this depends on the method of manufacturing the vapor deposition mask 1. In a case where the vapor deposition mask 1 is transparent, mechanical alignment and artificial alignment can be more easily and more accurately carried out.

Also, unlike carbon fiber and the like which is non-magnetic, the micro cellulose 2 has magnetic properties, and has an advantage that the micro cellulose 2 can be aligned by applying a magnetic field.

When the micro cellulose 2 is cellulose nanofibers, a cellulose nanofiber film can be formed by dispersing the cellulose nanofibers in an aqueous medium to produce a nanofiber dispersant liquid, applying the nanofiber dispersant liquid onto a supporting body such as a glass substrate or the like, and drying. In this case, the mask substrate 11 can be formed from cellulose nanofiber that is light and thin and has high strength, by adjusting the film thickness of the cellulose nanofiber, or layering a plurality of layers of cellulose nanofiber film either directly or using adhesive.

The nanofiber dispersant liquid can be produced by, for example, adding an aqueous medium to cellulose nanofiber precursor such as oxidized cellulose or the like obtained by the TEMPO oxidation process, to obtain an aqueous liquid blend, carrying out pH adjustment as appropriate, and carrying out a defibrillation process.

The aqueous medium can be, for example, water, a solvent mixture of organic solvent mixed with water, and the like. The organic solvent can be, for example, an alcohol, an ether, a ketone, and the like.

Also, the base material of the vapor deposition mask 1, for example, the base material of the mask substrate 11, or, the base material of the mask substrate 11 and the mask frame 21, may include a substance (material) other than the micro cellulose 2.

In FIG. 1, an example in which the micro cellulose 2 is mixed with a resin 3 is illustrated.

Resin (plastic material) that is the same as the resin used as the resin in commonly known resin vapor deposition masks can be used as the resin 3, which is combined with the micro cellulose 2.

A hardening resin such as thermosetting resin, photo curing resin (for example, ultraviolet photo curing resin), or the like are suited as the resin 3, as long as such a hardening resin does not plasticly deform at the vapor deposition temperature in forming the vapor deposition film 72. Therefore, the resin 3 is not limited to a hardening resin, but may be a thermoplastic resin when the gasification temperature (the evaporation temperature when the vapor deposition material is a liquid, and the sublimation temperature when the vapor deposition material is a solid) of the vapor deposition material is low and the resin 3 has a softening point (heat distortion temperature) higher than the vapor deposition temperature (for example, the above gasification temperature), or when the temperature at which the vapor deposition mask 1 is used is low, such as when at least one of the other constitutive elements in contact with the vapor deposition mask 1 (for example, the film formation target substrate 60, a retention member, and the like) includes a cooling member.

For example, polyimide resin, epoxy resin, acrylic resin, and the like can be used as the hardening resin. For example, polyimide has a high glass transition temperature equal to or higher than 400° C., is rigid and strong, and has high heat resistance, and thus polyimide is suited as a material of the vapor deposition mask 1. For example, thermoplastic polyimide resin, polyamide resin, polyethylene resin, polypropylene resin, polycarbonate resin, polystyrene resin, and the like can be used as the thermoplastic resin.

There is no particular limitation on the content of the micro cellulose 2 in the vapor deposition mask 1, as long as the material of the vapor deposition mask 1 includes the micro cellulose 2. However, to obtain sufficient strengthening effect from the micro cellulose 2, it may be desirable that the content of the micro cellulose 2 is at least 10 mass % with respect to the resin 3.

Also, the vapor deposition mask 1 may, for example, be a fiber reinforced composite vapor deposition mask (in other words, a fiber reinforced composite resin mask) that includes the micro cellulose 2, with the resin 3 as the base material (matrix resin). In this case, the content of the micro cellulose 2 is 50 mass % or less with respect to the resin 3.

Note that, in a case where the vapor deposition mask 1 includes the resin 3, as described above, a chemical modification or a hydrophobizing process may be carried out on the micro cellulose 2 to increase the affinity with the resin 3. Therefore, an additive such as a chemical modification agent or the like may be included in the material of the vapor deposition mask 1.

### Method of Manufacturing the Vapor Deposition Mask 1

FIGS. 5A and 5B are cross-sectional views illustrating a sequence of processes, as an example of a process for manufacturing the vapor deposition mask 1 according to the present embodiment.

The process for manufacturing the vapor deposition mask 1 includes, for example, a mask substrate forming process and an opening forming process.

In the mask substrate forming process, for example, first, the micro cellulose 2 and the resin raw material that is the raw material for the resin 3 are mixed to prepare a mixture liquid in which the micro cellulose 2 is dispersed in the resin raw material. Then, the mixture liquid is applied over a supporting body 91 such as a glass substrate or the like in a thin plate-like form as illustrated in FIG. 5A, and the thin plate-like coating film for constituting the mask substrate 11 that is applied over the supporting body 91 is, for example, heated or irradiated with light (for example, ultraviolet light irradiation) or the like to harden the resin 3. In this way, the mask substrate 11 is formed.

In the opening forming process, for example, the mask substrate 11 formed in the mask substrate forming process is irradiated with laser light as illustrated in FIG. 5B, to form the mask apertures 12 in the mask substrate 11. Then, the vapor deposition mask 1 according to the present embodiment is produced by fixing the mask substrate 11 to the mask frame 21 as appropriate, for example, as illustrated in FIG. 3A.

Note that the resin raw material that is mixed with the micro cellulose 2 may be hardening resin in liquid form, may be a resin precursor in liquid form, or may be melted thermoplastic resin.

Also, to obtain the resin raw material in liquid form or to adjust the viscosity, the resin 3 or a resin precursor that is the precursor of the resin 3 may be dissolved in a solvent such as an organic solvent or the like to produce a solution, or may be dispersed in a dispersion medium to produce a dispersion liquid.

In a case where a resin precursor is used as the resin raw material, after mixing the resin precursor and the micro cellulose 2, by polymerizing the resin precursor when processing (forming) into a thin plate form, the micro cellulose 2 can be bonded together by the resin 3.

For example, polyimide, in particular, aromatic polyimide is rigid and strong and has high heat resistance as stated above, so it is suitable as the material of the vapor deposition mask 1, but it is insoluble and infusible. Therefore, when polyimide is used as the resin 3, for example, polyamide acid that is the precursor of polyimide, and the micro cellulose 2 may be mixed to produce the mask substrate 11, then dewatering and a cyclization (imidization) reaction are carried out to convert the polyamide acid into polyimide.

Polyamide acid can be converted into polyimide by, for example, either thermal imidization using heat, chemical imidization using an imidizing catalyst, or by a combination of both. Note that there is no particular limitation on the imidization catalyst, and any commonly known imidization catalyst can be used, such as a heterocyclic compound containing nitrogen, an N-oxide compound of the heterocyclic compound containing nitrogen, an aromatic hydrocarbon compound having a hydroxyl group, an aromatic heterocyclic compound, and the like. Also, in the imidization reaction, carboxylic acid anhydride or the like may be used as a dewatering agent.

Therefore, depending on the type of the resin 3, the resin raw materials may include solvent or catalyst, dewatering agent, and the like, and may include a hardening agent or the like. The micro cellulose 2 may be directly mixed with the resin raw materials, or may be dispersed in a dispersion medium and mixed with the resin raw materials.

Note that there is no particular limitation on the solvent, as long as the solvent is capable of dissolving the resin 3 or the resin precursor that is the precursor of the resin 3. Also, there is no particular limitation on the dispersion medium, as long as the dispersion medium is capable of dispersing the resin 3 or the resin precursor that is the precursor of the resin 3.

The resin raw material and the micro cellulose 2 can be mixed by agitating the raw materials together. There is no particular limitation on the mixing machine used for mixing the resin raw materials and the micro cellulose 2, for example, various types of commercial mixing machine such as the finely dividing processing device described previously can be used.

Also, the forming conditions (film forming conditions) of the mask substrate 11 can be, for example, the same as the film forming conditions of the resin 3. In other words, the mask substrate 11 can be produced under the same conditions as the forming conditions of the resin 3 when the micro cellulose 2 is not included.

Note that in FIGS. 5A and 5B, as an example, illustrated is a case in which the mask substrate 11 is formed by thinly applying the mixture liquid in which the micro cellulose 2 is dispersed in the resin raw material onto the supporting body 91, such as a glass substrate or the like, and hardening it. However, the method of forming the mask substrate 11 is not limited to the method illustrated in FIGS. 5A and 5B, and various forming methods can be adopted in accordance with the type of the resin 3, for example, cast molding, a solution casting method, vacuum/compressed air forming, plastic forming, and the like.

Also, the forming temperature in the forming process (for example, the polymerization temperature, hardening temperature, and the like) and the forming time (for example, the polymerization time, hardening time), and the like may be set as appropriate in accordance with the type of the resin 3.

Note that when the micro cellulose 2 includes cellulose nanofibers as described previously, the mask substrate 11 can be produced by forming a cellulose nanofiber film by dispersing the cellulose nanofibers in an aqueous medium to produce a nanofiber dispersion liquid, applying the nanofiber dispersion liquid onto a supporting body such as a glass substrate or the like, and drying. Note that there is no particular limitation on the drying conditions in this case, as long as the cellulose nanofiber 11 can be formed.

In this case, the mask substrate 11 may be produced by, for example, either layering along the mask plane of the vapor deposition mask 1 a plurality of layers of cellulose nanofiber films to be oriented in one direction in the in-plane direction of the mask substrate 11, so that the direction of alignment of the cellulose nanofibers is the same direction, or alternatively layering so that the alignment directions of the cellulose nanofibers intersect (for example, at right angles), and applying pressure or heat, or bonding with adhesive or the like, as appropriate.

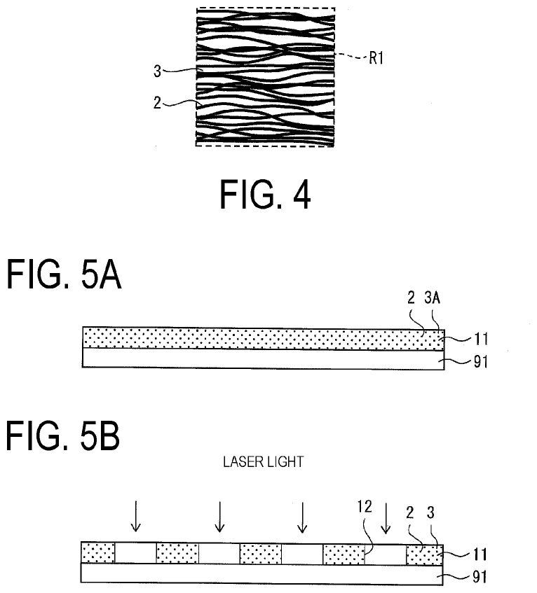

Also, FIG. 4 is a plan view illustrating an outline configuration of a relevant part of another vapor deposition mask 1 according to the present embodiment, in which the micro cellulose 2 is aligned in one direction (uniaxial alignment).

Note that in FIG. 4, as an example, illustrated is a fiber reinforced composite vapor deposition mask in which the vapor deposition mask 1 includes the micro cellulose 2, and the resin 3 as the base material (matrix resin), the same as for the vapor deposition mask 1 illustrated in FIG. 1. FIG. 4 corresponds to an enlargement of the portion of the vapor deposition mask 1 with the micro cellulose 2 aligned uniaxially, as indicated by the region R1 on FIG. 1.

As illustrated in FIG. 4, even when the vapor deposition mask 1 includes the resin 3, the micro cellulose 2 is aligned along the surface (mask surface) of the vapor deposition mask 1 in an in-plane direction (in-plane direction), and is substantially parallel to the mask plane of the vapor deposition mask 1. The micro cellulose 2 may be aligned parallel, and, for example, may be aligned uniaxially.

In this way, in the mask substrate 11 forming process, by aligning the micro cellulose 2 along the mask surface of the vapor deposition mask 1 (in other words, aligning parallel to the mask surface 1 of the vapor deposition mask 1), the film thickness of the vapor deposition mask 1 can be made thinner, and the film thickness of the mask substrate 11 can easily be adjusted to a desired film thickness. Also, fluffing on the surface of the vapor deposition mask 1 can be reduced or prevented, so a vapor deposition mask 1 with good usability and no fibers protruding from the surface of the vapor deposition mask 1 can be obtained.

Also, in a case where the vapor deposition mask 1 has a rectangular shape in plan view, the larger the vapor deposition mask 1, the more easily it can bend in the long direction due to its self weight. Therefore, when the vapor deposition mask 1 is a rectangular vapor deposition mask, by aligning the micro cellulose 2 along the long direction of the vapor deposition mask 1, bending (self-weight bending) in the long direction of the vapor deposition mask 1 can be reduced.

Also, when the vapor deposition mask 1 includes mask apertures 12 with a slit shape, by aligning the micro cellulose 2 along the forming direction of the slit shaped mask apertures 12, forming the mask apertures 12 is easier, and it is possible to reduce fluffing of the micro cellulose 2 in the mask apertures 12.

Alternatively, by manufacturing the mask substrate 11 by layering thin films that include micro cellulose 2, such as a cellulose nanofiber film, so that, for example, the alignment directions of the micro cellulose 2 are normal to each other, the strength of the mask substrate 11 can be further increased.

In particular, cellulose molecules have high strength, so by uniaxially aligning the micro cellulose 2, not only is the strength increased, but the micro cellulose 2 is arranged in parallel. Hence, by hydrogen bonding the micro cellulose 2, the gaps between adjacent micro cellulose 2 are further reduced, and the compactness is increased. As a result, the hydrogen bonds between adjacent micro cellulose 2 are strengthened, and the strength is also increased.

Note that the micro cellulose 2 is not necessarily all aligned in the same direction within the in-plane direction, and may include some of the micro cellulose 2 deviates in the alignment direction, but it may be desirable that the alignment direction of the micro cellulose 2 is uniform as much as possible.

### Alignment Treatment

There is no particular limitation on the method of aligning the direction of the micro cellulose 2, as long as the micro cellulose 2 can be aligned uniaxially.

For example, (1) the micro cellulose 2 can be uniaxially aligned by applying hot air from one direction onto the coating film that is applied on the supporting body 91 and that constitutes the mask substrate 1, in a wet state in which aqueous medium remains. The aqueous medium in the coating film flows in such one direction making the micro cellulose 2 flow, and the micro cellulose 2 can be aligned uniaxially.

Also, (2) by applying compression and shear deformation in the coating film thickness direction to the coating film in the wet state including the micro cellulose 2, such as a coating film formed from cellulose nanofiber dispersion liquid, the degree of planar alignment is improved by the hydrogen bonding between the micro cellulose 2 while being coated, and the micro cellulose 2 can be aligned along the coating film surface.

Also, (3) by uniaxially extending the coating film, the interaction effect of the hydrogen bonds, and the like, between the fibers of the micro cellulose 2 is weakened, and the micro cellulose 2 can be aligned uniaxially. Note that uniaxial extension may be carried out before drying the coating film, or may be carried out after drying, but may be desirable to be carried out before drying.

Also, (4) by rubbing the surface of the supporting body used for forming the coating film or the surface of the coating film in a constant direction (rubbing process), the micro cellulose 2 can the aligned uniaxially.

Also, (5) by forming the coating film by a high-speed (reverse) gravia method, (6) forming the coating film while applying an electric field, and (7) forming the coating film while applying a magnetic field, the micro cellulose 2 can be aligned uniaxially.

In particular, the micro cellulose 2 has magnetic properties as described previously, so by applying a magnetic field to the micro cellulose 2, the micro cellulose 2 can be easily aligned regardless of the thickness of the coating film or the presence or absence of the resin 3.

For example, by applying a rotating magnetic field to the micro cellulose 2, the axis of the fibers of the micro cellulose 2 are uniaxially aligned parallel with the rotational axis. Using this, the mask substrate 11 can be formed with the micro cellulose 2 oriented uniaxially, by forming the mask substrate 11 (or the mask substrate 11 with the mask frame) including the micro cellulose 2 or the micro cellulose 2 and the resin 3, as described above.

### Vapor Deposition Device 50

Next, an example of an outline configuration of the vapor deposition device 50 using the vapor deposition mask 1 is described below with reference to the FIG. 2.

As illustrated in FIG. 2, the vapor deposition device 50 according to the present embodiment includes the vapor deposition mask 1, a vapor deposition source 30, or vapor deposition source movement device that is not illustrated on the drawings, a substrate movement device that is not illustrated on the drawings, and a substrate holder that is not illustrated in the drawings.

The substrate holder serves as a holding member that holds the vapor deposition mask 1 and the film formation target substrate 60. The vapor deposition mask 1 is held in contact with the film formation target substrate 60 by the substrate holder of each film formation target substrate 60.

The vapor deposition source 30 is disposed opposite to the vapor deposition mask 1 on the opposite sides to the film formation target substrate 60. The vapor deposition source 30 serves as a container that holds vapor deposition material within. Note that the vapor deposition source 30 may be a container that directly contains vapor deposition material in the interior of the container, or may be formed having a load lock type tube so that the vapor deposition material can be supplied from outside.

The vapor deposition source 30 is formed, for example, in a rectangular shape. The vapor deposition source 30 includes a plurality of emission openings 31 (vapor deposition source openings, nozzles) on the top surface (in other words, the surface opposite to the vapor deposition mask 1) that emits the vapor deposition material as vapor deposition particles 71. The emission openings 31 are, for example, disposed in a one-dimensional manner (linear manner) or in a two-dimensional manner (planar (tile form)) with a constant pitch (in other words, distances between the centers of adjacent emission openings 31 are all equal). Note that, in FIG. 2, as an example, illustrated is a case in which the vapor deposition source 30 has a plurality of emission openings 31, but at least one emission opening 31 may be provided.

The vapor deposition source 30 generates vapor deposition particles in gaseous form by heating and gasifying (evaporating when the vapor deposition material is a liquid material, and sublimating when the vapor deposition material is a solid material) the vapor deposition material. The vapor deposition source 30 emits the vapor deposition material that has been gasified in this way from the emission openings 31 towards the vapor deposition mask 1, as vapor deposition particles 71.

According to the present embodiment, as described above, the vapor deposition mask 1 (for example, the mask substrate 11) includes micro cellulose 2 in the base material, and thus is lighter than a vapor deposition mask made from metal. Also, unlike a vapor deposition mask made from resin, it has high strength even when the thickness is reduced. Moreover, the vapor deposition film 72 can be formed with a high definition pattern.

### Second Embodiment

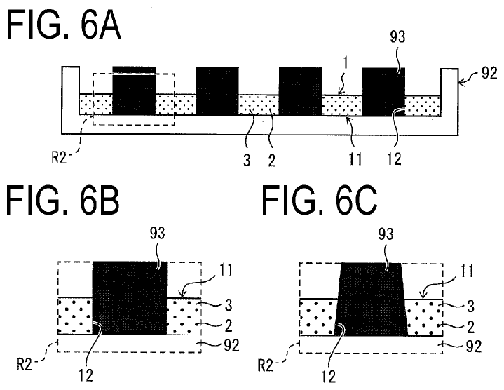

A description will be given of another embodiment of the disclosure, with reference to FIGS. 6A to 6C. The present embodiment will be stated by the differences between the present embodiment and the first embodiment, and components having the same function as the components stated in the first embodiment are given the same reference signs, and the description thereof is omitted.

### Method of Manufacturing the Vapor Deposition Mask 1

In the first embodiment, the method of manufacturing the vapor deposition mask 1 has been described in which, for example, the mask substrate 11 including the micro cellulose 2 is irradiated with laser light to form the mask apertures 12 in the mask substrate 11. However, the method of manufacturing the vapor deposition mask 1 is not limited to this method.

FIG. 6A is a cross-sectional view schematically illustrating the outline configuration of the mask substrate 11 in one process for manufacturing the vapor deposition mask 1 according to the present embodiment. FIG. 6B is a cross-sectional view schematically illustrating an outline configuration of relevant parts of the mask substrate 11 in a region R2 indicated in FIG. 6A. FIG. 6C is a cross-sectional view schematically illustrating another example of an outline configuration of relevant parts of the mask substrate 11 in the region R2 indicated in FIG. 6A. Note that the vapor deposition mask 1 illustrated in FIGS. 6A to 6C schematically depicts a cross section through the vapor deposition mask 1 corresponding to the cross section taken along line B-B in the direction of the arrows in FIG. 1.

Note that in FIGS. 6A to 6C, as an example, illustrated is a case in which the micro cellulose 2 is mixed with the resin 3. However, as described in the first embodiment, the vapor deposition mask 1 may not necessarily include the resin 3 in the base material, as long as the micro cellulose 2 is included in the base material.

In the present embodiment, as illustrated in FIG. 6A, the mask apertures 12 can be formed at the same time when the mask substrate 11 is formed, by forming the mask substrate 11 using a forming mold 92 having bulging portions 93 for forming the mask apertures 12 in the mask substrate 11. Therefore, according to the present embodiment, the mask substrate 11 in which the mask apertures 12 are formed can be manufactured by removing the mask substrate 11 from the forming mold 92.

Note that the forming conditions of the mask substrate 11 can be the same as the conditions in the first embodiment, and, for example, can be the same as the film forming conditions of the resin 3. In other words, also in the present embodiment, the mask substrate 11 can be produced under the same conditions as the forming conditions of the resin 3 in a case where the micro cellulose 2 is not included.

Also, in the present embodiment, the micro cellulose 2 can be aligned parallel to the main surface of the mask substrate 11, and the micro cellulose 2 can be aligned in a uniaxial direction, as illustrated in FIG. 6A to 6C, by the methods described in the first embodiment.

The bulging portions 93 may be formed from a removable material, for example, a material that can be melted. By forming the bulging portions 93 with a removable material, for example, a resist material or the like, the bulging portions 93 can be removed after the mask substrate 11 is formed, by using a solvent that can remove the material for constituting the bulging portions 93, for example, a resist removing agent.

Note that the mask substrate 11 may be removed from the forming mold 92 on which the bulging portions 93 are provided, by using a mold releasing agent or the like, without removing the bulging portions 93.

Also, for example, by changing the shape of the wall surfaces of the bulging portions 93 in the forming mold 92, as illustrated in FIGS. 6B and 6C, the shape of the mask apertures 12 in the mask substrate 11, for example, the taper angle of the mask apertures 12 can be changed.

The bulging portions 93 may be formed, for example, in a prismatic shape as illustrated in FIG. 6B, or may be formed with a forward tapered shape with the angle between the wall surface of the bulging portions 93 and the surface of the forming mold 92 on which the bulging portions 93 are formed (in other words, the interior wall of the forming mold 92) greater than 90°, as illustrated in FIG. 6C.

Note that in FIG. 6C, as an example, the case in which the bulging portions 93 have a forward taper is illustrated, but the bulging portions 93 may be formed with a reverse taper shape with the angle between the wall surface of the bulging portions 93 and the surface of the forming mold 92 on which the bulging portions 93 are formed smaller than 90°.

By forming the bulging portions 93 with a tapered shape (reverse tapered shape or forward tapered shape), the mask apertures 12 of the mask substrate 11 can have the same taper shape as the bulging portions 93.

By providing a slope to the aperture walls of the mask apertures 12 of the mask substrate 11 so that the aperture walls have a tapered shape, and arranging the vapor deposition mask 1 and the film formation target substrate 60 so that the size of the openings of the mask apertures 12 of the mask substrate 11 become smaller towards the film formation target substrate 60, shadows can be more effectively reduced.

According to the present embodiment, by forming the mask substrate 11 using the forming mold 92 as described above, the mask substrate 11 having the mask apertures 12 can be formed without separately carrying out laser irradiation or the like.

Also, according to the present embodiment, by forming the mask apertures 12 by removing the mold without carrying out laser irradiation, as described above, there is no micro cellulose 2 or resin 3 disposed in the forming region of the mask apertures 12. Therefore, waste of the micro cellulose 2 and the resin 3 can be eliminated, and the vapor deposition mask 1 can be produced at low cost.

Also, according to the present embodiment, by providing the bulging portions 93 on the forming mold 92 in the forming region of the mask apertures 12, the micro cellulose 2 will not protrude from the mask apertures 12. Also, in forming the mask apertures 12, the micro cellulose 2 is not cut at the wall surfaces of the mask apertures 12. Hence, end surfaces of the micro cellulose 2 that has been cut at the wall surfaces of the mask apertures 12 do not cause fluffing. Therefore, according to the present embodiment, the vapor deposition mask 1 can be provided with high accuracy, convenience of use, and low cost.

### Third Embodiment

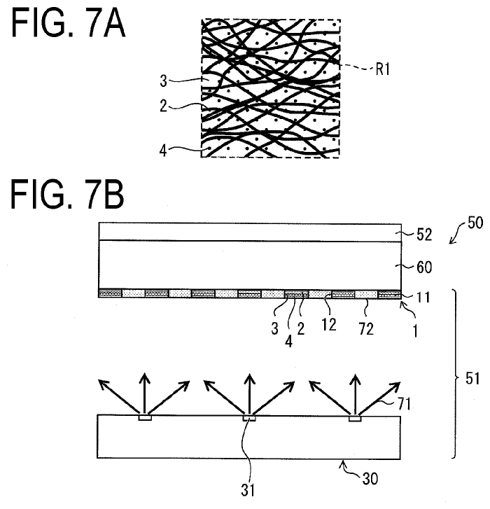

A description will be given of yet another embodiment of the disclosure, with reference to FIGS. 7A and 7B. The present embodiment will be stated by the differences between the present embodiment and the first and second embodiments. Components having the same function as the components stated in the first and second embodiments are given the same reference signs, and the description thereof is omitted.

### Outline Configuration of Vapor Deposition Mask 1

FIG. 7A is a plan view illustrating an outline configuration of a relevant part of the vapor deposition mask 1 according to the present embodiment. FIG. 7B illustrates an example of the outline configuration of a vapor deposition device 50 that includes the vapor deposition mask 1 according to the present embodiment. Note that FIG. 7A corresponds to a partial enlargement of the region R1 of the vapor deposition mask 1 indicated as outlined in FIG. 1. Also, the vapor deposition mask 1 illustrated in FIG. 7B schematically depicts a cross section through the vapor deposition mask 1 corresponding to the cross section taken along line A-A in the direction of the arrows in FIG. 1.

The vapor deposition mask 1 according to the present embodiment as illustrated in FIGS. 7A and 7B is the same as the vapor deposition mask 1 according to the first and second embodiments, except that magnetic particles 4 are further included in the base material. The vapor deposition mask 1 illustrated in FIGS. 7A and 7B is an example in which the magnetic particles 4 together with the micro cellulose 2 is mixed with the resin 3.

In the vapor deposition mask 1 according to the present embodiment, for example, a resin raw material that includes the micro cellulose 2 and the magnetic particles 4 is used, instead of the resin raw material that includes the micro cellulose 2 in the first and second embodiments, and can be produced by the same method as the first and second embodiments.

The magnetic particles 4 may be formed from a magnetic metal material having magnetic properties, such as, for example, iron, nickel, invar (and iron and nickel alloy), SUS430, and the like, or formed from Fe₂0₃ particles, Fe₃0₄ particles, or magnetic ceramic material such as ferrite or the like that includes these iron oxide particles. Also, the magnetic particles 4 may be particles in which the surface of base particles (core particles) is covered by the above materials that have magnetic properties.

There is no particular limitation on the particle size of the magnetic particles 4, but, for example, the average particle diameter (mass average particle diameter) may be less than 1 μm.

By further including the magnetic particles 4 in the vapor deposition mask 1 in this way, the vapor deposition mask 1 can further have stiffness, and the strength of the vapor deposition mask 1 can be further increased.

Also, by further including the magnetic particles 4 in the vapor deposition mask 1, the vapor deposition mask 1 can be attracted and held during vapor deposition by a magnetism generating source 52, for example, a magnet such as a magnet plate or the like, or an electromagnet or the like.

In the present embodiment, there is no particular limitation on the content of the magnetic particles 4 in the vapor deposition mask 1, and the content can be adjusted as desired to obtain a desired function in accordance with the materials used and a combination of the materials. By adjusting the type and the size of the magnetic particles 4, and the content of the magnetic particles 4 included in the vapor deposition mask 1, the properties, for example, the magnetic strength and the like, can be adjusted.

### Vapor Deposition Device 50

The vapor deposition device 50 according to the present embodiment is the same as the vapor deposition device 50 illustrated in FIG. 2, except that the magnetism generating source 52 is provided on the side opposite to the vapor deposition mask 1, with the film formation target substrate 60 interposed between the vapor deposition mask 1 and the magnetism generating source 52.

According to the present embodiment, the vapor deposition mask 1 further includes the magnetic particles 4, and the magnetism generating source 52 is provided on the side opposite to the vapor deposition mask 1 with the film formation target substrate 60 interposed between the vapor deposition mask 1 and the magnetism generating source 52. Therefore, the magnetic particles 4 and the micro cellulose 2 mixed into the base material are attracted by the magnetism towards the magnetism generating source 52. In this way, the vapor deposition mask 1 for each film formation target substrate 60 can be attracted to the magnetism generating source 52. Therefore, according to the present embodiment, the film formation target substrate 60 and the vapor deposition mass 1 can be fixed in close contact with each other.

### Modification

Note that in FIGS. 7A and 7B, as an example, the case in which the vapor deposition mask 1 includes the magnetic particles 4, which is a magnetic body in particulate form as magnetic body, has been described. However, the form of the magnetic body is not limited to such a particle form, and other forms may be used. Also, in the present embodiment, the resin 3 may be omitted, as in the first and second embodiments.

### Fourth Embodiment

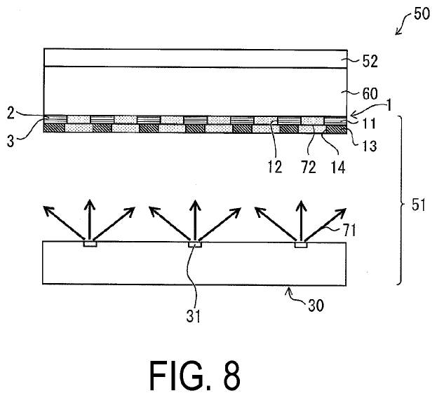

A description will be given of yet another embodiment of the disclosure, with reference to FIG. 8. The present embodiment will be stated by the differences between the present embodiment and the first to third embodiments. Components having the same function as the components stated in the first to third embodiments are appended with the same reference signs, and the description thereof is omitted.

### Outline Configuration of Vapor Deposition Mask 1

FIG. 8 illustrates an example of the outline configuration of a vapor deposition device 50 that includes the vapor deposition mask 1 according to the present embodiment. Note that the vapor deposition mask 1 illustrated in FIG. 8 schematically depicts a cross section through the vapor deposition mask 1 corresponding to the cross section taken along line A-A in the direction of the arrows in FIG. 1.

In the first to third embodiments, examples have been described for the cases in which the vapor deposition mask 1 is a vapor deposition mask made from a micro cellulose film such as a cellulose nanofiber film, or, a fiber reinforced composite vapor deposition mask (fiber reinforced composite resin mask) made from a fiber reinforced composite resin material with the resin 3 as the base material (matrix resin). However, the configuration of the vapor deposition mask 1 is not limited to the above configurations.

For example, as illustrated in FIG. 8, the vapor deposition mask 1 according to the present embodiment may be a vapor deposition mask that includes the mask substrate 11, which is a fiber reinforced composite resin mask that includes the resin 3 and the micro cellulose 2 in the base material, and a mask substrate made from metal (hereafter, referred to as a “metal mask substrate 13” to distinguish it from the mask substrate 11). The vapor deposition mask may be a metal mask provided with mask apertures (hereafter, referred to as “metal mask apertures 14” to distinguish them from the mask apertures 12) that are layered.

By making the vapor deposition mask 1 have a layered structure that includes the mask substrate 11 (first mask substrate) and the metal mask substrate 13 (second mask substrate), the strength of the vapor deposition mask 1 can be further increased.

The metal mask apertures 14 (second apertures) are formed larger than the mask apertures 12 (first apertures). The metal mask apertures 14 and the mask apertures 12 may be provided on a one-to-one basis. As long as the mask apertures 12 are provided within the metal mask apertures 14 in plan view, so that through apertures that pass through the vapor deposition mask 1 are formed in the vapor deposition mask 1 (in other words, the mass apertures 12 and the metal mask apertures 14 are superimposed in plan view), only one mask aperture 12 may be provided within one metal mask aperture 14, or a plurality of mass apertures 12 may be provided within one metal mask aperture 14.

In this way, in the present embodiment, communication openings respectively including the metal mask apertures 14 and the mask apertures 12 are provided in the vapor deposition mask 1, as through apertures.

The metal mask substrate 13 is formed, for example, to the same size (size in plan view) as the mask substrate 11 in plan view. However, the present embodiment is not limited to the above configuration, and the metal mask substrate 13 and the mask substrate 11 may not necessarily have the same size, as long as the mask apertures 12 of the mask substrate 11 are formed to overlap with the metal mask apertures 14 of the metal mask substrate 13.

### Method of Manufacturing the Vapor Deposition Mask 1

The mask substrate 11 and the metal mask substrate 13 may be layered with adhesive or the like interposed between the mask substrate 11 and the metal mask substrate 13. However, the mask substrate 11 and the metal mask substrate 13 may contact each other and may be integrated without adhesive interposed between the mask substrate 11 and the metal mask substrate 13.

The vapor deposition mask 1 according to the present embodiment can be manufactured, for example, by using the metal mask substrate 13 (metal plate) prior to forming of the metal mask apertures 14, instead of the supporting body 91 illustrated in FIG. 5A. After the metal mask apertures 14 is formed in the metal mask substrate 13 by applying a photoresist and photolithography is performed on the surface of the metal mask substrate 13 on which the mask substrate 11 is not provided, the mask apertures 12 is formed in the mask substrate 11 by irradiating with laser light the portions of the mask substrate 11 located within the mask apertures 14 in plan view, either from the mask substrate 11 side or from the metal mask substrate 13 side.

### Vapor Deposition Device 50

The vapor deposition device 50 according to the present embodiment has the same structure as the vapor deposition device 50 according to the third embodiment, except that it has the layered structure of the mask substrate 11 and the metal mask substrate 13 as illustrated in FIG. 8.

According to the present embodiment, the vapor deposition mask 1 further includes the metal mask substrate 13, and the magnetism generating source 52 is provided on the side opposite to the vapor deposition mask 1 with the film formation target substrate 60 interposed between the vapor deposition mask 1 and the magnetism generating source 52. Also, the micro cellulose 2 in the mask substrate 11 is attracted by the magnetism towards the magnetism generating source 52. In this way, the vapor deposition mask 1 for each film formation target substrate 60 can be attracted to the magnetism generating source 52. Therefore, also in the present embodiment, the film formation target substrate 60 and the vapor deposition mass 1 can be fixed in close contact with each other.

In the vapor deposition mask 1, the mask substrate 11 is disposed in a position on the film formation target substrate 60 side of the metal mask substrate 13. In this way the vapor deposition film 72 is formed on the film formation target substrate 60 by the vapor deposition particles 71 emitted from the emission openings 31 of the vapor deposition source 30 after they have passed through the mask apertures 12 after passing through the metal mask apertures 14.

### Fifth Embodiment

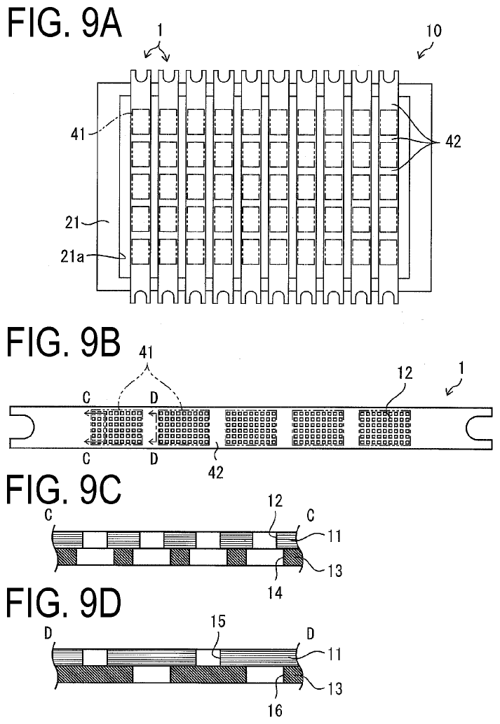

A description will be given of yet another embodiment of the disclosure, with reference to FIGS. 9A to 9D. The present embodiment will be stated by the differences between the present embodiment and the first to third embodiments, and components having the same function as the components stated in the first to third embodiments are given the same reference signs, and the description thereof is omitted.

### Outline Configuration of Vapor Deposition Mask 1

FIG. 9A is a plan view illustrating an outline configuration of a relevant part of a mask unit 10 that includes the vapor deposition mask 1 according to the present embodiment. FIG. 9B is a plan view illustrating an outline configuration of the vapor deposition mask 1 illustrated in FIG. 9A. FIG. 9C is a cross-sectional view of the vapor deposition mask 1 taken along line C-C and in the direction of the arrows illustrated in FIG. 9B. FIG. 9D is a cross-sectional view of the vapor deposition mask 1 taken along line D-D and in the direction of the arrows illustrated on FIG. 9B.

As illustrated in FIG. 9A, the mask unit 10 according to the present embodiment includes a plurality of vapor deposition masks 1, and the mask frame 21 (frame) installed on the peripheral portions of the plurality of the vapor deposition masks 1.

The vapor deposition mask 1 according to the present embodiment has a substantially rectangular shape (strip form) in outline in plan view, as illustrated in FIGS. 9A and 9B.

The mask frame 21 holds the vapor deposition masks 1 in a stretched state, so that the vapor deposition masks 1 do not bend. The vapor deposition masks 1 and the mask frame 21 are fixed together by, for example, spot welding. The mask frame 21 includes, for example, beam members that are not illustrated on the drawings that support the vapor deposition masks and that span in lattice form on the mask frame 21. In plan view, the spaces between the mask frame 21 and the vapor deposition masks 1 and the spaces between adjacent vapor deposition masks 1 are closed by the beam members.

As illustrated in FIGS. 9A and 9B, the vapor deposition mask 1 is positioned within an opening 21a of the mask frame 21, and includes an effective region 41 in which openings are formed passing through the vapor deposition mask 1, and a peripheral region 42 that surrounds the effective region 41. At least one effective region 41 is provided in the long direction of the vapor deposition mask 1 (in the example illustrated in FIGS. 9A and 9B, a plurality of effective region 41 are provided). As illustrated in FIGS. 9A and 9B, when a plurality of effective regions 41 is provided in one vapor deposition mask 1, a peripheral region 42 is provided surrounding each of the effective regions 41.

As illustrated in FIG. 9C, communication openings that respectively include the mask apertures 12 (first apertures) and the metal mask apertures 14 (second apertures) are formed in the effective regions 41, as through apertures that allowed the vapor deposition particles 71 to pass. Note that in FIG. 9A, the mask apertures 12 and the metal mask apertures 14 are omitted in the illustration. Also in FIG. 9B, the metal mask apertures 14 are not illustrated, and a number of the mask apertures 12 are omitted. Each effective region 41 corresponds, for example, to a display region of one EL display panel in an EL display device,

As illustrated in FIGS. 9A and 9B, the metal mask apertures 14 and the mask apertures 12 are, for example, each formed in a rectangular shape, and formed in a matrix form in the short direction and the long direction of the vapor deposition mask 1. However, the present embodiment is not limited to the above configuration. The metal mask apertures 14 and the mask apertures 12 may each be formed in slit form, and may each be formed arranged in a stripe form in the short direction of the vapor deposition mask 1.

Also in the present embodiment, the metal mask apertures 14 are formed larger than the mask apertures 12, as in the fourth embodiment. Note that in FIG. 9C, illustrated is a case in which the metal mask apertures 14 and the mask apertures 12 are provided on one-to-one basis, and are provided with the same pitch in the short direction of the vapor deposition mask 1. Note that here, the metal mask apertures 14 and the mask apertures 12 are provided with the same pitch indicates that a distance between the centers of adjacent metal mask apertures 14 and a distance between centers of adjacent mask apertures 12 are equal. However, the present embodiment is not limited to the above configuration, and as long as the mask apertures 12 are provided within the metal mask apertures 14 in plan view so that through apertures that pass through the vapor deposition mass 1 are formed in the vapor deposition mass 1, a plurality of mask apertures 12 may be provided within a single metal mask aperture 14.

On the other hand, the peripheral region 42 is a region that supports the effective region 41. The peripheral region 42 overlaps with a non-display region (casing region) surrounding the display region in the film formation target substrate 60.

Also, the vapor deposition mask 1 includes two side end portions G1 and G2 that extend to the outside of the mask frame 21 and that can be gripped. Each of the side end portions G1 and G2 has a notched shape in the center.

The portions located on the two sides of the notch of the side end portion G1 are each clamped by the corresponding one of two grippers that are not illustrated on the drawings, whereas the portions located on the two sides of the notch of the side end portion G2 are each clamped by the corresponding one of two grippers that are not illustrated on the drawings. Tension force is applied to the vapor deposition mask 1 by the four grippers, and by independently adjusting each of the grippers, the vapor deposition mask 1 is positioned relative to the mask frame 21. Note that the grippers are removed after completing the positioning of the vapor deposition mask 1 as described above, and after welding the vapor deposition mask 1 to the mask frame 21.

Positioning of the vapor deposition mask 1 relative to the mask frame 21 is carried out so that the position of the through apertures in the effective region 41 coincides with a pixel region (light emitting region) of the film formation target substrate 60. At this time, in a case where the effective region 41 largely deforms, the positioning may be difficult.

As illustrated in FIG. 9D, only mask apertures 15 (third apertures) that pass through the mask substrate 11 are provided in the mask substrate 11 (first mask substrate) in the peripheral region 42. On the other hand, only metal mask apertures 16 (fourth apertures) that pass through the metal mask substrate 13 are provided in the metal mask substrate 13 (second mask substrate) in the peripheral region 42. Note that in FIGS. 9A and 9B, the mask apertures 15 and the metal mask apertures 16 are omitted in the illustration.

As illustrated in FIG. 9D, the mask apertures 15 and the metal mask apertures 16 do not overlap with each other in plan view, and are provided in mutually different positions. Note that as long as the mask apertures 15 and the metal mask apertures 16 do not overlap with each other in plan view, the pitch of the mask apertures 15 (the distance between the centers of adjacent mask apertures 15) and the pitch of the metal mask apertures 16 (the distance between the centers of adjacent metal mask apertures 16) may be the same or may be different.

In other words, as long as at least one of the pitch of the mask apertures 15 and the pitch of the metal mask apertures 16 is formed to be different from the pitch of the mask apertures 12 (distance between the centers of adjacent mask apertures 12) and the pitch of the metal mask apertures 14 (distance between centers of adjacent metal mask apertures 14), the pitch of the mask apertures 15 and the pitch of the metal mask apertures 16 may be the same or may be different.

The mask apertures 12 and the mask apertures 15 can be easily formed by using, for example, the same method, for example, at the same time, or by using the same laser light radiation unit. Also, the metal mask apertures 14 and the metal mask apertures 16 can be easily formed for example by the same method, and, for example, at the same time. For example, a process of forming the mask apertures 15 (third aperture forming process) may be carried out at the same time as a process of forming the mask apertures 12 (first aperture forming process), and a process of forming the metal mask apertures 16 (fourth aperture forming process) may be carried out at the same time as a process of forming the metal mask apertures 14 (second aperture forming process).

By covering the mask apertures 15 with the metal mask substrate 13, and covering the metal mask apertures 16 with the mask substrate 11, no through aperture is arranged in the peripheral region 42 of the vapor deposition mask 1, and recessed portions respectively constituted by the mask apertures 15 are arranged on the mask substrate 11 side, and recessed portions respectively constituted by the metal mask apertures 16 are arranged on the metal mask aperture 13 side. Therefore, the vapor deposition particles 71 emitted from the vapor deposition source 30 that arrive at the peripheral region 42 are blocked at the peripheral region 42, and do not arrive at the non-display region. Of the vapor deposition particles 71 that arrive at the effective region 41, only the vapor deposition particles 71 that pass through the metal mask apertures 14 and the mask apertures 12 arrive at the pixel area (light-emitting region).

In a case where the vapor deposition mask 1 includes the effective region 41 that has low stiffness and that includes the mask apertures 12 and the metal mask apertures 14, and the peripheral region 42 that has high stiffness and in which the recessed portions including the mask apertures 15 and the metal mask apertures 16 are not formed, the difference in stiffness between the effective region 41 and the peripheral region 42 is large and thus the vapor deposition mask 1 deforms, when the vapor deposition mask 1 spans across the mask frame 21.

However, in the present embodiment, by forming the recessed portions from the mask apertures 15 and the recessed portions from the metal mask apertures 16 as stress relieving portions in the peripheral region 42, as illustrated in FIG. 9D, the stiffness of the peripheral region 42 is reduced. Therefore, when the vapor deposition mask 1 is tensioned, the stress in the peripheral region 42 is relieved, and the stress applied to the effective region 41 and the peripheral region 42 of the vapor deposition mask 1 can be maintained uniform. The deformation of the vapor deposition mask 1 when tensioned (in particular, the deformation of the effective region 41) can be reduced.

Also, the vapor deposition mask 1 illustrated in FIG. 9D includes in the peripheral region 42 both the recessed portions as stress relieving portions, and high stiffness regions in which neither the mask apertures 15 nor the metal mask apertures 16 are formed and which have a total thickness of the thickness of the mask substrate 11 and the metal mask substrate 13 (in other words, the regions of the vapor deposition mask 1 having the maximum thickness). Therefore, the deformation of the effective region can be more effectively reduced.

### Modification

Note that in FIG. 9D, as an example, illustrated is a case in which the mask apertures 15 covered by the metal mask substrate 13 (in other words, the mask apertures 15 blocked by the metal mask substrate 13) are provided in the mask substrate 11 in the peripheral region 42, and the metal mask apertures 16 covered by the mask substrate 11 (in other words, the mask apertures 16 blocked by the mask substrate 11) are provided in the metal mask substrate 13 in the peripheral region 42.

However, the present embodiment is not limited to the above configuration, and the vapor deposition mask 1 may have a configuration in which either one of the mask apertures 15 or the metal mask apertures 16 is provided in the peripheral region 42.

### Supplement

The vapor deposition mask 1 according to a first aspect of the disclosure includes: a first mask substrate (mask substrate 11). The first mask substrate includes a first aperture (mask aperture 12) for causing a vapor deposition particle 71 for forming a vapor deposition film 72 on a film formation target substrate 60 to pass. A base material of the first mask substrate includes micro cellulose 2 in fiber form.

In the vapor deposition mask 1 according to a second aspect of the disclosure, the micro cellulose 2, in the first aspect, may include cellulose nanofibers.

In the vapor deposition mask 1 according to a third aspect of the disclosure, the micro cellulose 2, in the first or second aspect, may be aligned within a plane along a surface of the first mask substrate.

In the vapor deposition mask 1 according to a fourth aspect of the disclosure, the micro cellulose 2, in any of the first to third aspects, may be aligned in one direction.

In the vapor deposition mask 1 according to a fifth aspect of the disclosure, the vapor deposition mask 1, in the third or fourth aspect, has an external shape that is rectangular in plan view, and the micro cellulose 2 may be aligned in a long direction of the vapor deposition mask 1.

In the vapor deposition mask 1 according to a sixth aspect of the disclosure, the micro cellulose 2, in any of the first to fifth aspects, may be mixed with resin.

In the vapor deposition mask 1 according to a seventh aspect of the disclosure, the base material of the sixth aspect may further include a magnetic body (for example, a magnetic particle 4).

In the vapor deposition mask 1 according to an eighth aspect of the disclosure, the vapor deposition mask 1, in any one of the first to seventh aspects, further includes a second mass substrate (metal mass substrate 13) including metal, the second mass substrate including a second aperture (metal mask aperture 14) for causing the vapor deposition particle to pass. The first mask substrate and the second mask substrate may be layered to be superimposed with each other in plan view.

In the vapor deposition mask 1 according to a ninth aspect of the disclosure, the vapor deposition mask 1, in the eighth aspect, further includes an effective region 41 including the first aperture and the second aperture, and a peripheral region 42 for surrounding the effective region 41. The peripheral region 42 of the first mask substrate 1 may include a third aperture (mask aperture 15) to be blocked by the second mask substrate.

In the vapor deposition mask 1 according to a tenth aspect of the disclosure, the peripheral region 42 of the second mask substrate in the ninth aspect may include a fourth aperture (metal mask aperture 16) to be blocked by the first mask substrate.

In the vapor deposition mask 1 according to an eleventh aspect of the disclosure, the vapor deposition mask in the eighth aspect may further include an effective region 41 in which the first aperture and the second aperture are formed, and a peripheral region 42 for surrounding the effective region. The peripheral region 42 in the second mask substrate includes a fourth aperture to be blocked by the first mask substrate.

A vapor deposition device 50 according to a twelfth aspect of the disclosure includes: the vapor deposition mask 1 according to any one of the first to eleventh aspects; and a vapor deposition source 30 configured to emit a vapor deposition particle 71 towards the vapor deposition mask 1.

A method of manufacturing a vapor deposition mask 1 according to a thirteenth aspect of the disclosure, the vapor deposition mask 1 including a first mask substrate (mask substrate 11) including a first aperture (mask aperture 12) for causing a vapor deposition particle 71 for forming a vapor deposition film 72 on a film formation target substrate 60 to pass, the method includes: forming the first mask substrate. In the forming, the first mask substrate including micro cellulose 2 in a base material is formed by using a material including the micro cellulose 2 in fiber form.

In the method of manufacturing the vapor deposition mask 1 according to a fourteenth aspect of the disclosure, in the forming in the thirteenth aspect, an alignment treatment may be carried out on the micro cellulose 2.

In the method of manufacturing the vapor deposition mask 1 according to a fifteenth aspect of the disclosure, the alignment treatment in the fourteenth aspect is carried out by forming the first mask substrate while applying a magnetic field.

In the method of manufacturing the vapor deposition mask according to a sixteenth aspect of the disclosure, the forming in any of the thirteenth to fifteenth aspects may further include forming the first aperture in the first mask substrate by irradiating the first mask substrate formed in the forming with laser light.

In the method of manufacturing the vapor deposition mask according to a seventeenth aspect of the disclosure, in the forming of any of the thirteenth to fifteenth aspects, the first mask substrate is formed by using a forming mold 92 including a bulging portion 93 corresponding to a forming region of the first aperture in the first mask substrate.

In the method of manufacturing the vapor deposition mask according to an eighteenth aspect of the disclosure, in the seventeenth aspect, the bulging portion 93 is provided such that it can be removed, and after the first mask substrate is formed the bulging portion is removed.

In the method of manufacturing the vapor deposition mask according to a nineteenth aspect of the disclosure, in the forming in any of the thirteenth to fifteenth aspects, the first mask substrate is formed on a second mask substrate including metal. The method includes: forming a first aperture on the first mask substrate, and forming a second aperture (metal mask aperture 14) on the second mask substrate for causing the vapor deposition particle to pass. In the first aperture forming and in the second aperture forming, the first aperture and the second aperture are formed to overlap with each other in plan view.

In the method of manufacturing the vapor deposition mask 1 according to a twentieth aspect of the disclosure, in the nineteenth aspect, the vapor deposition mask includes an effective region 41 in which the first aperture and the second aperture are formed, and a peripheral region 42 for surrounding the effective region 41. The method may further include forming a third aperture (mask aperture 15) in the peripheral region 42 of the first mask substrate to be blocked by the second mask substrate, and forming a fourth aperture (metal mask aperture 16) in the peripheral region 42 of the second mask aperture to be blocked by the first mask aperture.

In the method of manufacturing the vapor deposition mask 1 according to a twenty-first aspect of the disclosure, the micro cellulose in any of the thirteenth to twentieth aspects may be mixed with resin.

In the method of manufacturing the vapor deposition mask 1 according to a twenty-second aspect of the disclosure, the base material of the twenty-first aspect may further include a magnetic body.

The method of manufacturing an electroluminescence display device according to a twenty-third aspect of the disclosure is a method of manufacturing an electroluminescence display device in which a vapor deposition film 72 is formed on a film formation target substrate 60 by using the vapor deposition mask 1 according to any of the first to eleventh aspects. The vapor deposition film 72 is a light emitting layer of the electroluminescence display device. The film formation target substrate 60 is an electrode substrate of the electroluminescence display device, and the light emitting layer is formed as a film on the electrode substrate.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### INDUSTRIAL APPLICABILITY

1 Vapor deposition mask
2 Micro cellulose
3 Resin
4 Magnetic particle (magnetic body)
11 Mask substrate (first mask substrate)
12 Mask aperture (first mask aperture)
13 Metal mask substrate (second mask substrate)
14 Metal mask aperture (second aperture)
15 Mask aperture (third mask aperture)
16 Metal mask aperture (fourth aperture)
21 Mask frame
30 Vapor deposition source
31 Emission opening
41 Effective region
42 Peripheral region
50 Vapor deposition device
52 Magnetism generating source
60 Film formation target substrate
61 Film formation target surface
71 Vapor deposition particle
72 Vapor deposition film
91 Supporting body
92 Forming mold
93 Bulging portion

1-6. (canceled)

7. A vapor deposition mask comprising:
a first mask substrate including a first aperture for causing a vapor deposition particle for forming a vapor deposition film on a film formation target substrate to pass,
wherein a base material of the first mask substrate includes micro cellulose in fiber form,
the micro cellulose is mixed with resin, and
the base material further includes a magnetic body.

8. A vapor deposition mask comprising:
a first mask substrate including a first aperture for causing a vapor deposition particle for forming a vapor deposition film on a film formation target substrate to pass,
wherein a base material of the first mask substrate includes micro cellulose in fiber form;
the vapor deposition mask further comprising a second mask substrate including metal, the second mask substrate including a second aperture for causing the vapor deposition particle to pass,
wherein the first mask substrate and the second mask substrate are layered to overlap with each other in plan view.

9. The vapor deposition mask according to claim 8, further comprising:
an effective region including the first aperture and the second aperture; and
a peripheral region for surrounding the effective region,
wherein the peripheral region in the first mask substrate includes a third aperture to be blocked by the second mask substrate.

10. The vapor deposition mask according to claim 9,
wherein the peripheral region in the second mask substrate includes a fourth aperture to be blocked by the first mask substrate.

11. The vapor deposition mask according to claim 8, further comprising:
an effective region including the first aperture and the second aperture; and
a peripheral region for surrounding the effective region,
wherein the peripheral region in the second mask substrate includes a fourth aperture to be blocked by the first mask substrate.

12. A vapor deposition device comprising:
the vapor deposition mask according to claim 7; and
a vapor deposition source configured to emit the vapor deposition particle towards the vapor deposition mask.

13-14. (canceled)

15. A method of manufacturing the vapor deposition mask,
the vapor deposition mask including a first mask substrate including a first aperture for causing a vapor deposition particle for forming a vapor deposition film on a film formation target substrate to pass, the method comprising:
forming the first mask substrate;
wherein in the forming, the first mask substrate including micro cellulose in a base material is formed by using a material including micro cellulose in fiber form,
in the forming, an alignment treatment is carried out on the micro cellulose, and
the alignment treatment is carried out by forming the first mask substrate while applying a magnetic field.

16. The method of manufacturing the vapor deposition mask according to claim 15, further comprising:
forming the first aperture in the first mask substrate by irradiating the first mask substrate formed in the forming with laser light.

17. The method of manufacturing the vapor deposition mask according to claim 15,
wherein in the forming, the first mask substrate is formed by using a forming mold including a bulging portion corresponding to a forming region of the first aperture in the first mask substrate.

18. The method of manufacturing the vapor deposition mask according to claim 17,
wherein the bulging portion is removably provided, and after the first mask substrate is formed, the bulging portion is removed.

19. The method of manufacturing the vapor deposition mask according to claim 15,
wherein in the forming, the first mask substrate is formed on a second mask substrate including metal,
further comprising:
forming the first aperture in the first mask substrate; and
forming a second aperture on the second mask substrate for causing the vapor deposition particle to pass,
wherein in the forming of the first aperture and in the forming of the second aperture, the first aperture and the second aperture are formed to overlap with each other in plan view.

20. The method of manufacturing the vapor deposition mask according to claim 19,
wherein the vapor deposition mask includes an effective region in which the first aperture and the second aperture are formed, and a peripheral region for surrounding the effective region,
further comprising:
forming a third aperture in the peripheral region of the first mask substrate to be blocked by the second mask substrate; and
forming a fourth aperture in the peripheral region of the second mask aperture to be blocked by the first mask aperture.

21. The method of manufacturing the vapor deposition mask according to claim 15,
wherein the material includes micro cellulose mixed with resin.

22. The method of manufacturing the vapor deposition mask according to claim 21,
wherein the material further includes a magnetic body.

23. (canceled)

24. The vapor deposition mask according to claim 7,
further comprising a second mask substrate including metal, the second mask substrate including a second aperture for causing the vapor deposition particle to pass,
wherein the first mask substrate and the second mask substrate are layered to overlap with each other in plan view.

25. The vapor deposition mask according to claim 7,
wherein the micro cellulose includes a cellulose nanofiber.

26. The vapor deposition mask according to claim 7,
wherein the micro cellulose is aligned on a plane along a surface of the first mask substrate.

27. The vapor deposition mask according to claim 7,
wherein the micro cellulose is aligned in one direction.

28. The vapor deposition mask according to claim 7,
wherein the vapor deposition mask has an external shape that is rectangular in plan view, and the micro cellulose is aligned in a long direction of the vapor deposition mask.

29. The vapor deposition mask according to claim 8,
wherein the micro cellulose includes a cellulose nanofiber.
